(19) United States
(12) Patent Application Publication
(10) Pub. No.: US 2024/0090207 A1
(43) Pub. Date: Mar. 14, 2024

(54) SEMICONDUCTOR STRUCTURE AND FORMING METHOD THEREFOR, AND MEMORY

(71) Applicant: Changxin Memory Technologies, Inc., Hefei (CN)

(72) Inventors: Ran LI, Hefei (CN); Biao Zang, Hefei (CN); Chih-Cheng Lin, Hefei (CN); Leilei Duan, Hefei (CN)

(21) Appl. No.: 18/511,914

(22) Filed: Nov. 16, 2023

Related U.S. Application Data
(63) Continuation of application No. PCT/CN2022/124203, filed on Oct. 9, 2022.

(30) Foreign Application Priority Data
Aug. 9, 2022 (CN) 202210952952.8

(51) Int. Cl. H10B 12/00

(52) U.S. Cl. CPC H10B 12/50; H10B 12/09; H10B 12/488

(57) ABSTRACT

A semiconductor structure includes a substrate and a word line structure. The substrate includes an array region and a peripheral region. The word line structure includes a first conductive layer disposed on the substrate, and the first conductive layer penetrates the array region and extends to the peripheral region in a first direction. In a normal direction of the substrate, a height of the first conductive layer on a surface of the peripheral region is higher than a height of the first conductive layer on a surface of the array region.

### CROSS-REFERENCE TO RELATED APPLICATIONS

This application is a continuation application of International Patent Application No. PCT/CN2022/124203, filed on Oct. 9, 2022, which claims priority to Chinese Patent Application No. 202210952952.8, filed on Aug. 9, 2022 and entitled “SEMICONDUCTOR STRUCTURE AND FORMING METHOD THEREFOR, AND MEMORY”. The above-referenced applications are incorporated herein by reference in their entireties.

### TECHNICAL FIELD

Various embodiments of the present invention relate to the field of semiconductor technologies, and in particular, to a semiconductor structure and a forming method therefor, and a memory.

### BACKGROUND

A dynamic random access memory (DRAM) is widely used in mobile devices such as mobile phones and tablet computers thanks to its advantages such as small size, high integration, and fast transmission speed. As a core component of DRAM, the word line structure plays a crucial role in electrical performances of a device.

In the DRAM, the word line structure generally needs to be electrically led out by a word line contact plug. In the process of making such word line structure, the word line contact plug needs to penetrate the second conductive layer on the surface of the word line structure to be connected to the word line structure. However, in the process of etching the second conductive layer, the substrate is prone to damages, resulting in a relatively low product yield.

It should be noted that the information disclosed in the BACKGROUND section is used merely to enhance understanding of the background of the present invention, and therefore may include information that does not constitute the prior art known to a person of ordinary skill in the art.

### SUMMARY

In view of the foregoing, a semiconductor structure and a forming method therefor, and a memory are provided in some implementations of the present invention, to reduce process difficulty and improve a product yield.

According to an aspect of the present invention, a semiconductor structure is provided. The semiconductor structure includes a substrate and a word line structure. The substrate includes an array region and a peripheral region and the word line structure includes a first conductive layer disposed on the substrate. The first conductive layer penetrates the array region and extends to the peripheral region in a first direction. In a normal direction of the substrate, a height of the first conductive layer on a surface of the peripheral region is higher than a height of the first conductive layer on a surface of the array region.

In some example embodiments of the present invention, the semiconductor structure further includes: a word line contact plug which is disposed in the peripheral region. A bottom surface of the word line contact plug is connected to the first conductive layer.

In some example embodiments of the present invention, the word line structure further includes a second conductive layer. The second conductive layer is disposed on the first conductive layer. The orthographic projection of the second conductive layer on the substrate does not overlap an orthographic projection of the word line contact plug on the substrate.

In some example embodiments of the present invention, one end of the second conductive layer close to the peripheral region and the word line contact plug are separated by a first distance. The first distance is less than a length of the first conductive layer in the peripheral region in the first direction.

In some example embodiments of the present invention, a surface of the first conductive layer in the peripheral region is flush with a surface of the second conductive layer.

In some example embodiments of the present invention, a material of the first conductive layer is a metal material. A material of the second conductive layer is a semiconductor material.

In some example embodiments of the present invention, the semiconductor structure further includes a peripheral contact plug disposed in the peripheral region and electrically connected to the word line contact plug. In the normal direction of the substrate, a top surface of the peripheral contact plug has a same height as a top surface of the word line contact plug.

In some example embodiments of the present invention, the word line structure further includes a gate dielectric layer. The gate dielectric layer at least conformally covers sidewall surfaces of the first conductive layer and the second conductive layer.

According to an aspect of the present invention, a method for forming a semiconductor structure is provided. The method includes providing a substrate and forming a plurality of word line structures in the substrate. The substrate includes an array region and a peripheral region. The word line structure includes a first conductive layer disposed on the substrate. The first conductive layer penetrates the array region and extends to the peripheral region in a first direction. In a normal direction of the substrate, a height of the first conductive layer on a surface of the peripheral region is higher than a height of the first conductive layer on a surface of the array region.

In some example embodiments of the present invention, the method further includes the step of forming a word line contact plug in the peripheral region. The bottom surface of the word line contact plug is connected to the first conductive layer.

In some example embodiments of the present invention, the method further includes the step of forming a second conductive layer on the first conductive layer. The orthographic projection of the second conductive layer on the substrate does not overlap an orthographic projection of the word line contact plug on the substrate.

In some example embodiments of the present invention, one end of the second conductive layer close to the peripheral region and the word line contact plug are separated by a first distance. The first distance is less than a length of the first conductive layer in the peripheral region in the first direction.

In some example embodiments of the present invention, a surface of the first conductive layer in the peripheral region is flush with a surface of the second conductive layer.

In some example embodiments of the present invention, a material of the first conductive layer is a metal material, and a material of the second conductive layer is a semiconductor material.

In some example embodiments of the present invention, the method further includes the step of forming a peripheral contact plug in the peripheral region. The peripheral contact plug is electrically connected to the word line contact plug. In the normal direction of the substrate, a top surface of the peripheral contact plug has the same height as a top surface of the word line contact plug.

In some example embodiments of the present invention, the word line structure further includes a gate dielectric layer. The gate dielectric layer at least conformally covers sidewall surfaces of the first conductive layer and the second conductive layer.

In some example embodiments of the present invention, the step of forming a plurality of word line structures in the substrate includes forming a plurality of word line trenches in the substrate, conformally forming, in each of the word line trenches, a gate dielectric layer that is attached to a sidewall of the word line trench, forming the first conductive layer in each of the word line trenches having the gate dielectric layer and forming the second conductive layer on a surface of the first conductive layer. The word line trenches penetrate the array region and the peripheral region.

In some example embodiments of the present invention, the step of forming the first conductive layer in each of the word line trenches having the gate dielectric layer includes forming a conductive material layer on a surface of the substrate, forming a second photoresist layer on a surface of the conductive material layer, etching the conductive material layer partially disposed in the array region with the second photoresist layer served as a mask, until a surface of the conductive material layer in the array region is flush with the surface of the substrate, removing the second photoresist layer and etching a remaining conductive material layer until a surface of the conductive material layer disposed in the peripheral region is lower than a surface of the substrate and higher than the surface of the conductive material layer disposed in the array region. The conductive material layer fills the word line trench having the gate dielectric layer. The orthographic projection of the second photoresist layer on the substrate coincides the peripheral region.

In some example embodiments of the present invention, the step of forming the second conductive layer on a surface of the first conductive layer includes forming a semiconductor material layer on a surface of a structure that is jointly formed by the gate dielectric layer, the first conductive layer, and the substrate, and removing the semiconductor material layer disposed outside the word line trench, and continuing to remove a part of the semiconductor material layer until a surface of the semiconductor material layer disposed in the array region is flush with a surface of the first conductive layer disposed in the peripheral region.

According to an aspect of the present invention, a memory is provided, which includes the semiconductor structures according to any of above.

It should be understood that the above-mentioned general descriptions and the following detailed descriptions are merely examples and explanations, and are not intended to limit the present invention.

### BRIEF DESCRIPTION OF DRAWINGS

The accompanying drawings, which are incorporated in and form a part of this specification, illustrate some embodiments consistent with the present invention and, in conjunction with the specification, serve to explain the principles of the present invention. It is obvious that the accompanying drawings in the following descriptions merely illustrate some embodiments of the present invention, and a person of ordinary skill in the art can derive other drawings from these accompanying drawings without creative efforts.

FIG. 1 is a schematic diagram of a word line structure in a related technology;

FIG. 2 is a top view of a semiconductor structure according to some implementations of the present invention;

FIG. 3 is a cross-sectional view of a semiconductor structure taken along a direction bb′ in FIG. 2 according to some implementations of the present invention;

FIG. 4 is a top view of a substrate according to some implementations of the present invention;

FIG. 5 is a cross-sectional view taken along a direction aa′ in FIG. 4 according to some implementations of the present invention;

FIG. 6 is a cross-sectional view taken along a direction bb′ in FIG. 4 according to some implementations of the present invention;

FIG. 7 is a cross-sectional view of a first conductive layer taken along a direction aa′ in FIG. 4 according to some implementations of the present invention;

FIG. 8 is a cross-sectional view of a first conductive layer taken along a direction bb′ in FIG. 4 according to some implementations of the present invention;

FIG. 9 is a cross-sectional view of an insulating layer taken along a direction aa′ in FIG. 4 according to some implementations of the present invention;

FIG. 10 is a cross-sectional view of an insulating layer taken along a direction bb′ in FIG. 4 according to some implementations of the present invention;

FIG. 11 is a cross-sectional view of a word line contact plug taken along a direction aa′ in FIG. 4 according to some implementations of the present invention;

FIG. 12 is a cross-sectional view of a word line contact plug taken along a direction bb′ in FIG. 4 according to some implementations of the present invention;

FIG. 13 is a cross-sectional view of a peripheral contact plug in a peripheral region according to some implementations of the present invention;

FIG. 14 is a flowchart of a method for forming a semiconductor structure according to some implementations of the present invention;

FIG. 15 is a cross-sectional view taken along a direction aa′ in FIG. 4 after step S2301 is completed according to some implementations of the present invention;

FIG. 16 is a cross-sectional view taken along a direction bb′ in FIG. 4 after step S2301 is completed according to some implementations of the present invention;

FIG. 17 is a cross-sectional view taken along a direction aa′ in FIG. 4 after step S2302 is completed according to some implementations of the present invention;

FIG. 18 is a cross-sectional view taken along a direction bb′ in FIG. 4 after step S2302 is completed according to some implementations of the present invention;

FIG. 19 is a cross-sectional view taken along a direction bb′ in FIG. 4 after step S2303 is completed according to some implementations of the present invention;

FIG. 20 is a cross-sectional view taken along a direction aa′ in FIG. 4 after step S320 is completed according to some implementations of the present invention;

FIG. 21 is a cross-sectional view taken along a direction bb′ in FIG. 4 after step S320 is completed according to some implementations of the present invention;

FIG. 22 is a cross-sectional view taken along a direction aa′ in FIG. 4 after step S1401 is completed according to some implementations of the present invention;

FIG. 23 is a cross-sectional view taken along a direction bb′ in FIG. 4 after step S1401 is completed according to some implementations of the present invention; and

FIG. 24 is a cross-sectional view of a second contact hole according to some implementations of the present invention.

### DESCRIPTION OF EMBODIMENTS

Example implementations are more comprehensively described below with reference to the accompanying drawings. However, the example implementations can be implemented in a plurality of forms, and should not be construed as being limited to some implementations described herein. On the contrary, these implementations are provided to make the present invention more comprehensive, and to convey the concept of the example implementations to a person skilled in the art. A same reference numeral in the figures represents a same or similar structure, and therefore detailed descriptions of the structure are omitted. In addition, the drawings are merely example illustrations of the present invention and are not necessarily drawn to scale.

Although relative terms such as “up” and “down” are used in this specification to describe a relative relationship of one component with respect to another component shown in the drawings, these terms are used in this specification for convenience purposes only, for example, based on an example direction described in the accompanying drawings. It can be understood that, if an apparatus shown in the drawings is flipped to make the apparatus upside down, a component described as “up” becomes a component described as “down”. When a structure is “on” another structure, it may mean that a structure is integrated on another structure, or that a structure is “directly” disposed on another structure, or that a structure is “indirectly” disposed on another structure by using an intermediate structure.

The terms “one”, “a/an”, “said”, “the”, and “at least one” are used to indicate presence of one or more elements/components/etc. The terms “comprise”, “include”, and “have” are used to mean an open-ended inclusion and indicate presence of additional elements/components/etc. in addition to the listed elements/components/etc. The terms “first”, “second”, and the like are used for marking purposes only, and are not intended to limit a quantity of objects indicated by these terms.

A word line structure is one of core components of a dynamic random access memory (DRAM). In a fabricating process, as shown in FIG. 1, a word line structure is generally embedded into the substrate 100 for space saving. The word line structure generally includes a first conductive layer 200 and a second conductive layer 300 that are stacked, and the word line structure is electrically led out by a lead connected to the word line structure. In the process of forming the lead, to reduce resistance, during formation of a via hole 400 that accommodates the lead, the second conductive layer 300 needs to be etched to expose the first conductive layer 200 below the second conductive layer 300. However, physical and chemical properties of a material of the second conductive layer 300 are generally similar to those of a material of an active region in the substrate 100. Consequently, the active region is easily damaged in the process of etching the second conductive layer 300, resulting in a relatively low product yield.

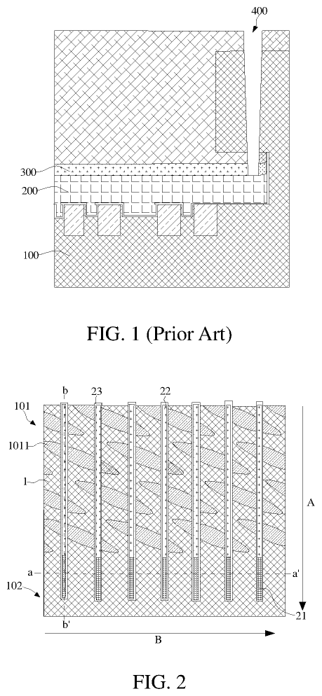

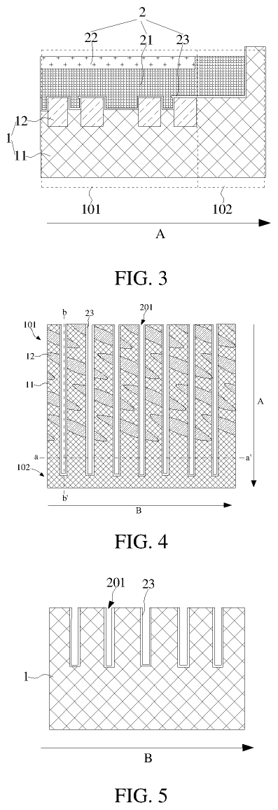

Some implementations of the present invention provide a semiconductor structure. FIG. 2 is a top view of a semiconductor structure according to some implementations of the present invention. FIG. 3 is a cross-sectional view of a semiconductor structure taken along a direction bb′ in FIG. 2 according to some implementations of the present invention. Referring to FIG. 2 and FIG. 3, the semiconductor structure may include a substrate 1 and a word line structure 2.

The substrate 1 may include an array region 101 and a peripheral region 102.

The word line structure 2 may include a first conductive layer 21 disposed on (and within the boundary of) the substrate 1. The first conductive layer 21 penetrates the array region 101 and extends to the peripheral region 102 in a first direction A. In a normal direction of the substrate 1, a height of the first conductive layer 21 on a surface of the peripheral region 102 is higher than a height of the first conductive layer 21 on a surface of the array region 102.

According to the semiconductor structure in some implementations of the present invention, since the height of the first conductive layer 21 on the surface of the peripheral region 102 is higher than the height of the first conductive layer 21 on the surface of the array region 101, the subsequently-formed second conductive layer 22 may be formed on the surface of the first conductive layer 21 in the array region 101. In some embodiments, the second conductive layer 22 may not be formed in the peripheral region 102. When the word line contact plug connected to the word line structure 2 is subsequently formed at the peripheral region 102, a via hole that is used to accommodate the word line contact plug does not need to penetrate the second conductive layer 22, and therefore, no etching solution or etching gas with a relatively high etching rate is required to etch the second conductive layer 22, thereby avoiding damages to the substrate 1 and the array region 101 in a process of forming the via hole. As such, defects generated in the substrate 1 are reduced, and a product yield is improved. In addition, in the above-mentioned process, because no second conductive layer 22 is disposed on the peripheral region 102, in a subsequent process of forming a via hole, there is no need to etch the second conductive layer 22, thereby reducing the layers to be etched, simplifying the manufacturing process (that is, reducing a process of etching the second conductive layer 22), and reducing manufacturing costs. In addition, because the height of the first conductive layer 21 is increased, the depth for etching the via hole is reduced, and processing difficulties may be reduced.

The following describes in detail the parts of the semiconductor structure in some implementations of the present invention.

As shown in FIG. 4 to FIG. 6, the substrate 1 may be of a flat plate structure. The substrate 1 may be of a rectangular, circular, oval, polygonal, or irregular pattern. A material of the substrate 1 may be a semiconductor material, for example, a material of the substrate 1 may be silicon, but is not limited to silicon or another semiconductor material. A shape and a material of the substrate 1 are not specifically limited herein.

In some implementations of the present invention, as shown in FIG. 4, the substrate 1 may be a silicon substrate, and a shallow trench isolation structure 11 is formed inside the substrate 1. The shallow trench isolation structure 11 may be formed by forming a trench in the substrate 1 and then filling the trench with an isolation material layer. A material of the shallow trench isolation structure 11 may include silicon nitride, silicon oxide, or the like, which is not specifically limited herein. A cross-sectional shape of the shallow trench isolation structure 11 may be set according to an actual requirement. The shallow trench isolation structure 11 may separate the substrate 1 into some active regions 12.

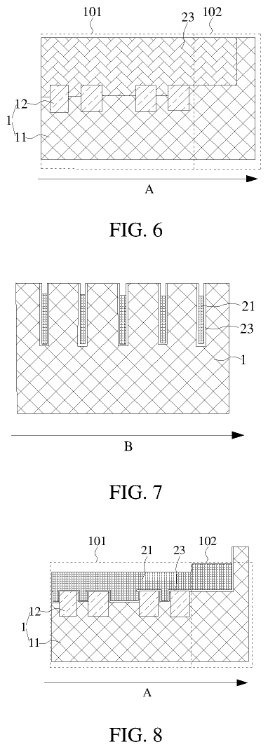

In some implementations of the present invention, referring to FIG. 6, the substrate 1 may include an array region 101 and a peripheral region 102. The array region 101 may be adjacent to the peripheral region 102. The peripheral region 102 may be disposed on a side of the array region 101, or may surround an outer circumference of the array region 101. The array region 101 may be configured to form a capacitor array, a transistor array, and a word line structure 2 and a bit line structure that connect the transistors and capacitors. A word line contact plug may be disposed at the peripheral region 102. The word line contact plug may connect the word line structure to a word line driver, a sense amplifier, a row decoder, a column decoder, and/or a controlling circuitry having special functions that are disposed in the peripheral region 102. The controlling circuitry may implement write and read functions of the transistors and capacitors by controlling a word line and a bit line. For example, the array region 101 may be a circular region, a rectangular region, or an irregular pattern region, or other shaped regions, which is not specifically limited herein. The peripheral region 102 may be, for example, a ring region and may surround an outer circumference of the array region 101, or may be a circular ring region, a rectangular ring region, or a ring region of another shape. Each active region 12 may be disposed in the array region 101, and the active regions 12 may be arranged in an array in the array region 101.

It should be noted that in some embodiments, there could be no clear boundary between the peripheral region 102 and the array region 101. In some embodiments, the boundary between the peripheral region 102 and the array region 101 is defined by the connection lines of endpoints of the second conductive layer 22. There is a distance between an edge of the peripheral region 102 and a side edge of the active region 12, and a region within the distance may be part of the array region 101.

In some example implementations of the present invention, referring to FIG. 4 and FIG. 5, the substrate 1 may include a plurality of word line trenches 201 extending in a first direction A, and the word line trenches 201 may be arranged at intervals in a second direction B. The word line trench 201 may be a groove-like structure recessed inwardly into the substrate 1, and a bottom end of the word line trench 201 is communicated with the substrate 1. In the first direction A, the word line trench 201 may penetrate the array region 101 and the peripheral region 102, and some of the word line trenches 201, disposed in the array region 101, may penetrate a plurality of active regions 12.

The first direction A may intersect the second direction B. For example, the first direction A and the second direction B may be perpendicular to each other. It should be noted that “perpendicular” may be absolutely perpendicular or may be substantially perpendicular. A deviation is inevitable in a manufacturing process. In some implementations of the present invention, an angle deviation may be caused due to a limitation of the manufacturing process, and consequently, there is a specific deviation in an included angle between the first direction A and the second direction B. It may be considered that the first direction A is perpendicular to the second direction B, provided that an angle deviation between the first direction A and the second direction B falls within a predetermined range. For example, the predetermined range may be 10°. In such case, it may be considered that the first direction A is perpendicular to the second direction B when the included angle between the first direction A and the second direction B is within a range greater than or equal to 80° and less than or equal to 100°.

Referring to FIG. 2 and FIG. 3, a word line structure 2 may be formed in each word line trench 201, that is, a plurality of word line structures 2 may be formed in the substrate 1. Each word line structure 2 may extend in the first direction A, and the plurality of word line structures 2 may be arranged at intervals in the second direction B.

In some implementations of the present invention, the word line structure 2 may penetrate the array region 101 and the peripheral region 102. For example, each word line structure 2 may extend from the peripheral region 102 to the array region 101, and some of the word line structures 2, disposed in the array region 101, may penetrate a plurality of active regions 12.

In some implementations of the present invention, referring to FIG. 7 and FIG. 8, the word line structure 2 may include a first conductive layer 21. The first conductive layer 21 may penetrate the array region 101 and extend to the peripheral region 102. A height of the first conductive layer 21 on a surface of the peripheral region 102 may be higher than a height of the first conductive layer 21 on a surface of the array region 101, to facilitate a word line contact plug to be subsequently formed in the peripheral region 102.

In some example implementations of the present invention, a material of the first conductive layer 21 may be a metal material. For example, the material of the first conductive layer 21 may be one of tungsten, titanium, and tantalum.

In some example implementations of the present invention, referring to FIG. 2 and FIG. 3, the word line structure 2 may further include a second conductive layer 22, and the second conductive layer 22 may be disposed on the first conductive layer 21, and is in contact with the first conductive layer 21.

In some example implementations of the present invention, the material of the second conductive layer 22 may be a semiconductor material, and the semiconductor material may be a material with a low work function. For example, the material of the second conductive layer 22 may be polysilicon. When the gate threshold voltage of the word line structure 2 is fulfilled, a second conductive layer 22 with a low work function may be disposed on a surface of the first conductive layer 21, and a gate-induced drain leakage (GIDL) current is reduced by using the second conductive layer 22.

In some example implementations of the present invention, referring to FIG. 2 to FIG. 8, the word line structure 2 may further include a gate dielectric layer 23, which may at least conformally be disposed on surfaces of sidewalls of the first conductive layer 21 and the second conductive layer 22, and may be a thin film formed on the surfaces of the sidewalls of the first conductive layer 21 and the second conductive layer 22.

In some example implementations of the present invention, referring to FIG. 5 to FIG. 7, the gate dielectric layer 23 may be conformally formed on and attached to a sidewall and a surface of each word line trench 201. A material of the gate dielectric layer 23 may include silicon oxide, silicon nitride, silicon oxynitride, or the like, or may be a combination of the above-mentioned materials. A thickness of the gate dielectric layer 23 may be 1 nm to 9 nm, for example, may be 1 nm, 2 nm, 4 nm, 6 nm, 8 nm, or 9 nm, or another thickness.

For example, the gate dielectric layer 23 may be conformally formed on and attached to a sidewall and a bottom of each word line trench 201 through chemical vapor deposition, physical vapor deposition, atomic layer deposition, thermal evaporation, thermal oxidation, or the like. in some embodiments, the gate dielectric layer 23 may be formed with another method, which is not specifically limited herein. For process convenience, in some embodiments, the gate dielectric layer 23 can be deposited over the substrate 1. Then, the gate dielectric layer 23 disposed on the surface of the substrate 1 can be removed, and only the gate dielectric layer 23 disposed on a sidewall and a bottom of each word line trench 201 is retained.

In some implementations of the present invention, a thermal oxidation process may be used to treat a surface of the gate dielectric layer 23 to improve the density of the gate dielectric layer 23, thereby reducing a leakage current and improving a gate control capability. In addition, the gate dielectric layer 23 may be a better barrier to impurities in the substrate 1 after the thermal oxidation to avoid diffusion of impurities in the substrate 1 into the word line trench 201, thereby improving structural stability.

In some implementations of the present invention, a diffusion barrier layer may be formed on the surface of the gate dielectric layer 23 to avoid diffusion of a metal material to the substrate 1 and avoid increasing a risk of the leakage current. The diffusion barrier layer may be conformally attached to the surface of the gate dielectric layer 23, that is, the gate dielectric layer 23 may be disposed between the diffusion barrier layer and the wall of the word line trench 201. A material of the diffusion barrier layer may be titanium nitride, and a thickness of the diffusion barrier layer may be 0.5 nm to 2 nm, for example, may be 0.5 nm, 1 nm, 1.5 nm, or 2 nm. In some implementations, the diffusion barrier layer may be formed on the surface of the gate dielectric layer 23 by using a process such as chemical vapor deposition, physical vapor deposition, or atomic layer deposition. The method of forming the diffusion barrier layer is not specifically limited herein.

In some example implementations of the present invention, a word line trench 201 in which a gate dielectric layer 23 is formed may be filled with a conductive material through chemical vapor deposition, physical vapor deposition, atomic layer deposition, vacuum evaporation, magnetron sputtering, thermal evaporation, or the like to form a first conductive layer 21 in the word line trench 201. It should be noted that, in a normal direction of the substrate 1, a height of a surface of the first conductive layer 21 in the peripheral region 102 is higher than a height of a surface of the first conductive layer 21 in the array region 101.

It should be noted that when a diffusion barrier layer is formed on the surface of the gate dielectric layer 23, the first conductive layer 21 may be formed on the surface of the diffusion barrier layer, that is, the word line trench 201 in which the gate dielectric layer 23 and the diffusion barrier layer are formed may be filled with a conductive material to form the first conductive layer 21 in the word line trench 201.

A second conductive layer 22 may be formed on a surface of the first conductive layer 21 by using a process such as physical vapor deposition, chemical vapor deposition, atomic layer deposition, vacuum evaporation, or magnetron sputtering. The second conductive layer 22 may cover a surface of the first conductive layer 21 disposed in the array region 101. An orthographic projection of the second conductive layer 22 on the substrate 1 does not overlap the peripheral region 102, and the orthographic projection of the second conductive layer 22 on the substrate 1 may overlap the array region 101.

In some example implementations of the present invention, referring to FIG. 2 and FIG. 3, a thickness of the second conductive layer 22 may be equal to a height difference between the first conductive layer 21 at the array region 101 and the first conductive layer 21 at the peripheral region 102, that is, a surface of the second conductive layer 22 may be flush with a surface of the first conductive layer 21 at the peripheral region 102, and the second conductive layer 22 covers only the surface of the first conductive layer 21 in the array region 101. In such case, compared with a conventional technology (in which the second conductive layer 22 covers the entire surface of the first conductive layer 21), when the structure formed by the second conductive layer 22 and the first conductive layer 21 occupies a same space, a volume ratio of the first conductive layer 21 to the second conductive layer 22 in the word line structure 2 in the present invention is higher than that in the conventional technology. Because a material of the first conductive layer 21 is a metal material, a proportion of a metal material in the word line structure 2 can be increased, thereby reducing the resistance of the word line structure 2.

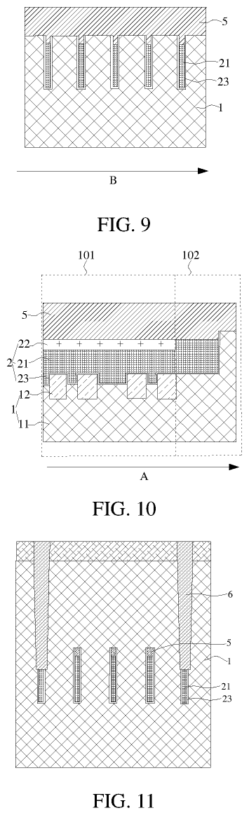

In some example implementations of the present invention, as shown in FIG. 9 and FIG. 10, the semiconductor structure may further include an insulating layer 5. The insulating layer 5 may be a film formed on top of the word line structure 2, or may be a coating formed on top of the word line structure 2. The form of the insulating layer 5 is not specifically limited herein. An orthographic projection of the insulating layer 5 on the substrate 1 may cover an orthographic projection of each word line structure 2 on the substrate 1. The insulating layer 5 may protect the word line structure 2 to avoid damages to the surface of the word line structure 2. In addition, the word line structure 2 may be isolated from another structure by using the insulating layer 5 to avoid coupling or a short circuit between the word line structure 2 and other structures, thereby improving a product yield.

In some implementations of the present invention, the insulating layer 5 may cover both the surface of the second conductive layer 22 and the surface of the first conductive layer 21 disposed on the surface of the peripheral region 102, that is, the insulating layer 5 may cover a surface of a structure that is jointly formed by the first conductive layer 21 and the second conductive layer 22. The insulating layer 5 may protect the first conductive layer 21 and the second conductive layer 22 to avoid damages to the surfaces of the first conductive layer 21 and the second conductive layer 22. In addition, the first conductive layer 21 and the second conductive layer 22 may be isolated from another structure by the insulating layer 5, to avoid coupling or a short circuit between another structure and each of the first conductive layer 21 and the second conductive layer 22, thereby increasing a product yield.

For example, a material of the insulating layer 5 may be silicon nitride or another insulating material. The insulating layer 5 may be formed, through chemical vapor deposition, physical vapor deposition, atomic layer deposition, thermal evaporation, vacuum evaporation, magnetron sputtering, or the like, on the surface of the structure jointly formed by the first conductive layer 21 and the second conductive layer 22. Obviously, the insulating layer 5 may alternatively be formed in another method. A method for forming the insulating layer 5 is not specifically limited herein.

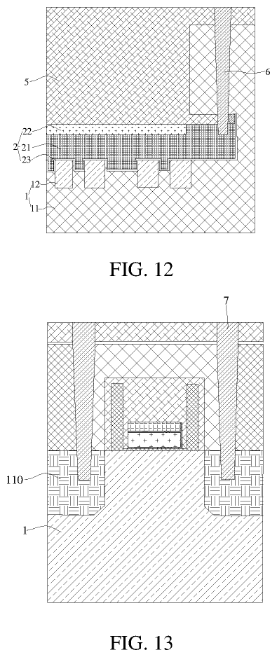

In some example implementations of the present invention, as shown in FIG. 11 and FIG. 12, the semiconductor structure may further include a word line contact plug 6, and the word line contact plug 6 may be formed in the peripheral region 102, that is, an orthographic projection of the second conductive layer 22 on the substrate 1 does not overlap an orthographic projection of the word line contact plug 6 on the substrate 1. In addition, the second conductive layer 22 may be spaced apart from the word line contact plug 6. For example, there may be a first distance between one end of the second conductive layer 22 close to the peripheral region 102 and the word line contact plug 6. The first distance may be less than a length of the first conductive layer 21 in the peripheral region 102 in the first direction A, thereby isolating the word line contact plug 6 from the second conductive layer 22, and avoiding damages to the second conductive layer 22 caused by formation of the word line contact plug 6.

Referring to FIG. 12, a bottom surface of the word line contact plug 6 may be directly connected to the surface of the first conductive layer 21 disposed in the peripheral region 102, so that the word line structure 2 is electrically led out by using the word line contact plug 6. Further, a data signal in the word line structure 2 may be led out by the word line contact plug 6.

In some implementations of the present invention, one end of the word line contact plug 6 is connected to the word line structure 2, and the other end of the word line contact plug 6 may be connected, by using a peripheral contact plug 7, to a word line driver, a sense amplifier, a row decoder, a column decoder, and/or a controlling circuitry having special functions. The controlling circuitry may control the word line structure 2 and the bit line structure through current transfer by the word line contact plug 6, thereby implementing write and read functions of the transistors and capacitors.

In some implementations of the present invention, referring to FIG. 12, the word line contact plug 6 may penetrate the insulating layer 5 in a normal direction of the substrate 1, that is, the word line contact plug 6 may be embedded into the insulating layer 5. The insulating layer 5 may protect the word line contact plug 6. In such a process, coupling or a short circuit between the word line contact plug 6 and another surrounding structure may be avoided, thereby further improving a product yield.

In some example implementations of the present invention, as shown in FIG. 13, the semiconductor structure may further include a peripheral contact plug 7. The peripheral contact plug 7 may be disposed in the peripheral region 102. One end of the peripheral contact plug 7 may be connected to a source/drain 110 of a transistor in the peripheral region 102. In the normal direction of the substrate 1, the peripheral contact plug 7 may penetrate the insulating layer 5, and be spaced from the word line contact plug 6. A height of a top surface of the peripheral contact plug 7 may be the same as that of a top surface of the word line contact plug 6.

In some implementations of the present invention, the peripheral contact plug 7 may be electrically connected to the word line contact plug 6 by using a connection wire disposed on the surface of the insulating layer 5, so that the peripheral circuit can control components in the array region 101.

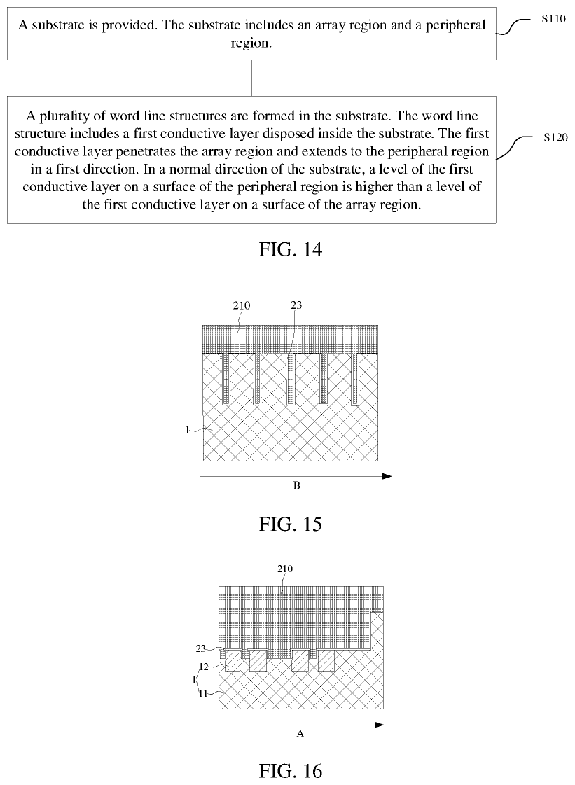

Some implementations of the present invention further provide a method for forming the semiconductor structure. FIG. 14 is a flowchart of a method of forming the semiconductor structures according to some implementations of the present invention. Referring to FIG. 14, the forming method in some implementations of the present invention may include step S110 and step S120.

In step 110 (S110), a substrate is provided. The substrate includes an array region and a peripheral region.

In step 120 (S120), a plurality of word line structures in the substrate are formed. Each of the word line structures includes a first conductive layer disposed on the substrate. The first conductive layer penetrates the array region and extends to the peripheral region in a first direction. In a normal direction of the substrate, the height of the first conductive layer on a surface of the peripheral region is higher than that of the first conductive layer on the surface of the array region.

According to the method for forming a semiconductor structure in some implementations of the present invention, since the height of the first conductive layer 21 on the surface of the peripheral region 102 is higher than the height of the first conductive layer 21 on the surface of the array region 101, the subsequently formed second conductive layer 22 may be formed on the surface of the first conductive layer 21 in the array region 101. In such case, the second conductive layer 22 does not need to be formed in the peripheral region 102. When the word line contact plug 6 connected to the word line structure 2 is subsequently formed, a via hole that is used to accommodate the word line contact plug 6 does not need to penetrate the second conductive layer 22, and therefore, no etching solution or etching gas with a relatively high etching rate is required to etch the second conductive layer 22, thereby avoiding damage to the substrate 1 and the array region 101 in a process of forming the via hole. As such, the defects in the substrate 1 are reduced, and a product yield is improved. In addition, in the above-mentioned process, because no second conductive layer 22 is disposed on the peripheral region 102, in a subsequent process of forming a via hole, there is no need to etch the second conductive layer 22, thereby reducing the layers to be etched, simplifying the manufacturing process (that is, reducing a process of etching the second conductive layer 22), and reducing manufacturing costs. In addition, because the height of the first conductive layer 21 is increased, the depth for etching the via hole is reduced, and processing difficulty may be reduced.

The following describes in detail steps and specific details of the method for forming a semiconductor structure in some embodiments of the present invention.

As shown in FIG. 14, in the S110, a substrate is provided. The substrate includes an array region and a peripheral region.

As shown in FIG. 4 to FIG. 6, the substrate 1 may be of a flat plate structure. The substrate 1 may be of a rectangular, circular, oval, polygonal, or irregular pattern. A material of the substrate 1 may be a semiconductor material, for example, a material of the substrate 1 may be silicon, but is not limited to silicon or another semiconductor material. A shape and a material of the substrate 1 are not specifically limited herein.

In some implementations of the present invention, as shown in FIG. 4, the substrate 1 may be a silicon substrate, and a shallow trench isolation structure 11 is formed inside the substrate 1. The shallow trench isolation structure 11 may be formed by forming a trench in the substrate 1 and then filling the trench with an isolation material layer. A material of the shallow trench isolation structure 11 may include silicon nitride, silicon oxide, or the like, which is not specifically limited herein. A cross-sectional shape of the shallow trench isolation structure 11 may be set according to an actual requirement. The shallow trench isolation structure 11 can separate the substrate 1 into some active regions 12.

In some implementations of the present invention, referring to FIG. 6, the substrate 1 may include an array region 101 and a peripheral region 102. The array region 101 may be adjacent to the peripheral region 102. The peripheral region 102 may be disposed on a side of the array region 101, or may surround an outer circumference of the array region 101. The array region 101 may be configured to form a capacitor array, a transistor array, and a word line structure 2 and a bit line structure that connect the transistors and capacitors. A word line contact plug may be disposed at the peripheral region 102 to connect the word line structure to the peripheral circuit. The peripheral circuit may include a word line driver, a sense amplifier, a row decoder, a column decoder, and a controlling circuitry having a special function. The peripheral circuit may implement write and read functions of the transistors and capacitors by controlling a word line and a bit line. For example, the array region 101 may be a circular region, a rectangular region, or an irregular pattern region, or another shape, which is not specifically limited herein. The peripheral region 102 may be, for example, a ring region and may surround an outer circumference of the array region 101, or may be a circular ring region, a rectangular ring region, or a ring region of another shape. Each active region 12 may be disposed in the array region 101, and the active regions 12 may be arranged in an array in the array region 101.

In some embodiments, there is a distance between an edge of the peripheral region 102 and a side edge of the active region 12, and a region within the distance may be part of the array region 101.

As shown in FIG. 14, in S120, a plurality of word line structures are formed in the substrate. The word line structure includes a first conductive layer disposed on the substrate, and the first conductive layer penetrates the array region and extends to the peripheral region in a first direction; in a normal direction of the substrate. A height of the first conductive layer on a surface of the peripheral region is higher than a height of the first conductive layer on a surface of the array region.

Referring to FIG. 7 and FIG. 8, the word line structure 2 may include a first conductive layer 21. The first conductive layer 21 may penetrate the array region 101 and extend to the peripheral region 102, so that the first conductive layer 21 is in a step shape, facilitating subsequent formation of a word line contact plug 6 in the peripheral region 102.

In some example implementations of the present invention, a material of the first conductive layer 21 may be a metal material. For example, the material of the first conductive layer 21 may be one of tungsten, titanium, and tantalum.

In some example implementations of the present invention, referring to FIG. 2 and FIG. 3, the word line structure 2 may further include a second conductive layer 22, and the second conductive layer 22 may be disposed on the first conductive layer 21, and is directly connected to the first conductive layer 21.

In some example implementations of the present invention, the material of the second conductive layer 22 may be a semiconductor material, and the semiconductor material may be a material with a low work function. For example, the material of the second conductive layer 22 may be polysilicon. When a gate threshold voltage of the word line structure 2 is fulfilled, a second conductive layer 22 with a low work function may be disposed on a surface of the first conductive layer 21, and a gate-induced drain leakage (GIDL) current is reduced by using the second conductive layer 22.

In some example implementations of the present invention, Referring to FIG. 2 to FIG. 8, the word line structure 2 may further include a gate dielectric layer 23, which may at least conformally be disposed on surfaces of sidewalls of the first conductive layer 21 and the second conductive layer 22, and may be a thin film formed on the surfaces of the sidewalls of the first conductive layer 21 and the second conductive layer 22.

In some example implementations of the present invention, forming a plurality of word line structures 2 in the substrate 1 may include steps S210 to S240.

In step 210 (S210), a plurality of word line trenches 201 are formed in the substrate 1. The word line trenches 201 penetrate the array region 101 and the peripheral region 102.

Referring to FIG. 4 and FIG. 5, each word line trench 201 may extend in a first direction A, and the plurality of word line trenches 201 may be arranged at intervals in a second direction B. The word line trench 201 may be a groove-like structure formed by etching inwardly into the substrate 1, and a bottom end of the word line trench 201 is connected to the substrate 1. In the first direction A, the word line trench 201 may penetrate the array region 101 and the peripheral region 102, and some of the word line trenches 201, disposed in the array region 101, may penetrate a plurality of active regions 12.

In some implementations of the present invention, a plurality of word line trenches 201 are formed in the substrate 1, where the word line trenches 201 penetrate the array region 101 and the peripheral region 102 (that is, step S210), which may include steps S2101 to S2104.

In step 2101 (S2101), a mask layer is formed on the surface of the substrate 1.

In some implementations of the present invention, the mask layer may be formed on the surface of the substrate 1 through chemical vapor deposition, physical vapor deposition, vacuum evaporation, magnetron sputtering, atomic layer deposition, or another method. The mask layer may be a multi-layer film structure or a single-layer film structure. A material of the mask layer may be at least one of a polymer, SiO₂, SiN, polysilicon, and SiCN, or another suitable material.

In some implementations, the mask layer may be of a multi-layer structure, which may include a polymer layer, an oxide layer, and a hard mask layer. The polymer layer may be formed on the surface of the substrate 1 and the oxide layer may be disposed between the hard mask layer and the polymer layer. The polymer layer may be formed on the surface of the substrate 1 by using a chemical vapor deposition process, the oxide layer may be formed on a surface of the polymer layer by using a vacuum evaporation process, and the hard mask layer may be formed on a surface of the oxide layer by using an atomic layer deposition process.

In step 2102 (S2102), a first photoresist layer is formed on a surface of the mask layer.

The first photoresist layer may be formed on a surface, away from the substrate 1, of the mask layer through spin coating or another method. A material of the first photoresist layer may be positive photoresist or negative photoresist, which is not specifically limited herein.

In step 2103 (S2103), the first photoresist layer is exposed and developed to form a plurality of developing regions that extend in the first direction A and that are arranged at intervals in the second direction B. An orthographic projection of the developing region on the substrate 1 is located on the array region 101 and the peripheral region 102.

The first photoresist layer may be exposed by using a mask plate, and a pattern of the mask plate may match a pattern required by the word line trench 201. Subsequently, the exposed first photoresist layer may be developed to form the plurality of developing regions that extend in the first direction A and that are arranged at intervals in the second direction B. Each developing region may expose a surface of the mask layer, a pattern of the developing region may be the same as a pattern required by the word line trench 201, a size of the developing region may be the same as a size required by the word line trench 201. In other words, the developing region may be in a strip shape, and an orthographic projection of the developing region on the substrate 1 may traverse the array region 101 and the peripheral region 102. In some implementations of the present invention, the orthographic projection of the developing region on the substrate 1 may traverse the peripheral region 102 and a plurality of active regions 12.

IN step 2104 (S2104), the mask layer and the substrate 1 are etched in the developing region to form a plurality of word line trenches 201 that extend in the first direction A and that are arranged at intervals in the second direction B.

The mask layer may be etched in each developing region by using an anisotropic etching process, and the etching region may expose the substrate 1 to form a plurality of mask patterns on the mask layer. The mask patterns may be in a strip shape, and an orthographic projection of each mask pattern on the substrate 1 may traverse the array region 101 and the peripheral region 102. In some implementations of the present invention, the orthographic projection of the developing region on the substrate 1 may traverse the plurality of active regions 12. For example, a mask pattern may be a strip pattern extending in the first direction A, and a plurality of mask patterns may be arranged at intervals in the second direction B.

It should be noted that, when the mask layer is of a single-layer structure, a mask pattern may be formed by using a one-time etching process. When the mask layer is of a multi-layer structure, the thin film may be hierarchically etched, that is, one layer may be etched by using the one-time etching process, and the mask layer may be etched by using multiple rounds of etching processes, to form a mask pattern. In some implementations, a shape and a size of the mask pattern may be the same as a pattern and a size required by each word line trench 201.

It should be noted that after the above-mentioned etching processes are completed, the first photoresist layer may be removed through cleaning by using washing liquid or ashing, so that the mask layer with the mask pattern is no longer covered by the first photoresist layer.

The mask layer with the mask pattern may be used as a mask to anisotropically etch the substrate 1 to form the plurality of word line trenches 201 that extend in the first direction A and that are arranged at intervals in the second direction B.

In step 220 (S220), in each of the word line trenches 201, a gate dielectric layer 23 attached to a sidewall of the word line trench 201 is conformally formed.

Referring to FIG. 2 and FIG. 3, a word line structure 2 may be formed in each word line trench 201, that is, a plurality of word line structures 2 may be formed in the substrate 1, each word line structure 2 may extend in the first direction A, and the plurality of word line structures 2 may be arranged at intervals in the second direction B.

In some implementations of the present invention, the word line structure 2 may penetrate the array region 101 and the peripheral region 102. For example, each word line structure 2 may extend from the peripheral region 102 to the array region 101, and some of the word line structures 2, disposed in the array region 101, may penetrate a plurality of active regions 12.

Referring to FIG. 5 to FIG. 7, a gate dielectric layer 23 may be conformally formed on and attached to a sidewall and a surface of each word line trench 201. A material of the gate dielectric layer 23 may include silicon oxide, silicon nitride, silicon oxynitride, or the like, or may be a combination of the above-mentioned materials. A thickness of the gate dielectric layer 23 may be 1 nm to 9 nm, for example, may be 1 nm, 2 nm, 4 nm, 6 nm, 8 nm, or 9 nm, or certainly, may be another thickness, which is not listed one by one herein.

For example, a gate dielectric layer 23 may be conformally formed on and attached to a sidewall and a bottom of each word line trench 201 through chemical vapor deposition, physical vapor deposition, atomic layer deposition, thermal evaporation, thermal oxidation, or the like. In some embodiments, the gate dielectric layer 23 may be formed with another method, which is not specifically limited herein. For process convenience, in some embodiments, the gate dielectric layer 23 can be deposited over the substrate 1. Then, the gate dielectric layer 23 disposed on the top surface of the substrate 1 can be removed, and only the gate dielectric layer 23 disposed on a sidewall and a bottom of each word line trench 201 is retained.

In some implementations of the present invention, a thermal oxidation process may be used to process a surface of the gate dielectric layer 23 to improve the density of the gate dielectric layer 23, thereby reducing a leakage current and improving a gate control capability. In addition, the gate dielectric layer 23 may be a better barrier to impurities in the substrate 1 after the thermal oxidation to avoid diffusion of impurities in the substrate 1 into the word line trench 201, thereby improving structural stability.

In some implementations of the present invention, a diffusion barrier layer may be formed on the surface of the gate dielectric layer 23 to avoid diffusion of a metal material to the substrate 1 and avoid increasing a risk of the leakage current. The diffusion barrier layer may be conformally attached to the surface of the gate dielectric layer 23, that is, the gate dielectric layer 23 may be disposed between the diffusion barrier layer and the wall of the word line trench 201. A material of the diffusion barrier layer may be titanium nitride, and a thickness of the diffusion barrier layer may be 0.5 nm to 2 nm, for example, may be 0.5 nm, 1 nm, 1.5 nm, or 2 nm. In some implementations, the diffusion barrier layer may be formed on the surface of the gate dielectric layer 23 by using a process such as chemical vapor deposition, physical vapor deposition, or atomic layer deposition. The method of forming the diffusion barrier layer is not specifically limited herein.

In step 230 (S230), the first conductive layer 21 is formed in each of the word line trenches 201 having the gate dielectric layer 23.

In some example implementations of the present invention, a word line trench 201 in which a gate dielectric layer 23 is formed may be filled with a conductive material through chemical vapor deposition, physical vapor deposition, atomic layer deposition, vacuum evaporation, magnetron sputtering, thermal evaporation, or the like to form a first conductive layer 21 in the word line trench 201.

It should be noted that when a diffusion barrier layer is formed on the surface of the gate dielectric layer 23, the first conductive layer 21 may be formed on the surface of the diffusion barrier layer, that is, the word line trench 201 in which the gate dielectric layer 23 and the diffusion barrier layer are formed may be filled with a conductive material to form the first conductive layer 21 in the word line trench 201.

In some example implementations of the present invention, the forming the first conductive layer 21 in each of the word line trenches 201 having the gate dielectric layer 23 (that is, step S230) may include steps S2301 to S2305.

In step 2301 (S2301), a conductive material layer 210 is formed on a surface of the substrate 1. The conductive material layer 210 fills each of the word line trenches 201 having the gate dielectric layer 23.

Referring to FIG. 15 and FIG. 16, each of the word line trenches 201 having the gate dielectric layer 23 may be filled with a conductive material through vacuum evaporation, magnetron sputtering, chemical vapor deposition, physical vapor deposition, atomic layer deposition, thermal evaporation, or the like. In some embodiments, each of the word line trenches 201 having the gate dielectric layer 23 may be filled with a conductive material by using another method. The conductive material may fill each of the word line trenches 201 to form a conductive material layer 210.

In step 2302 (S2302), a second photoresist layer 4 is formed on a surface of the conductive material layer 210. The orthographic projection of the second photoresist layer 4 on the substrate 1 coincides the peripheral region 102.

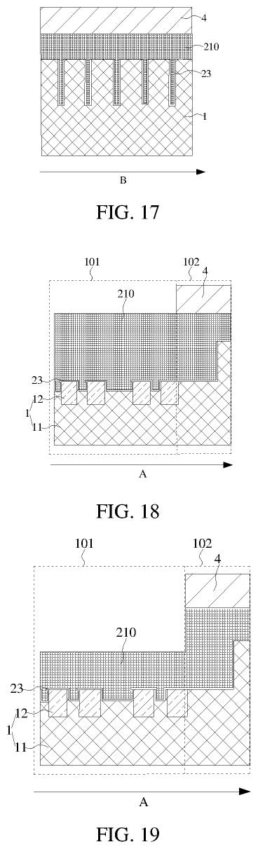

Referring to FIG. 17 and FIG. 18, the second photoresist layer 4 may be formed on a surface of the conductive material layer 210 through spin coating or another method. A material of the second photoresist layer 4 may be positive photoresist or negative photoresist, which is not specifically limited herein. It should be noted that the second photoresist layer 4 may cover a surface of the peripheral region 102, and an orthographic projection of the second photoresist layer 4 on the substrate 1 may coincide the peripheral region 102.

In step 2303 (S2303), the conductive material layer 210 partially disposed in the array region 101 is etched with the second photoresist layer 4 served as a mask, until a surface of the conductive material layer 210 in the array region 101 is flush with the surface of the substrate 1.

Referring to FIG. 19, the conductive material layer 210 that is not covered by the second photoresist layer 4 may be etched by using a dry etching process, and etching is stopped when a surface of the conductive material layer 210 that is not covered by the second photoresist layer 4 is flush with the surface of the substrate 1. In such case, a surface of the conductive material layer 210 in a region that is not covered by the photoresist layer is lower than a surface of the conductive material layer 210 in a region covered by the second photoresist layer 4, that is, a surface of the conductive material layer 210 disposed in the array region 101 is lower than a surface of the conductive material layer 210 disposed in the peripheral region 102. In some implementations of the present invention, an etching gas for dry etching may be carbon tetrafluoride. Certainly, the etching gas may alternatively be another gas, provided that the conductive material layer 210 can be removed without damaging another structure. Details are not listed one by one herein.

In step 2304 (S2304), the second photoresist layer 4 is removed.

The second photoresist layer 4 may be removed through cleaning by using washing liquid or ashing, so that the etched conductive material layer 210 is no longer covered by the second photoresist layer 4.

In step 2305 (S2305), a remaining conductive material layer 210 is etched until a surface of the conductive material layer 210 disposed in the peripheral region 102 is lower than a surface of the substrate 1.

The remaining conductive material layer 210 may be etched until the conductive material layer 210 disposed on the surface of the substrate 1 in the peripheral region 102 is completely removed. In addition, in the etching process, a surface of the conductive material layer 210 in the word line trench 201 may be lower than the surface of the substrate 1 to facilitate subsequent insulation and isolation of the surface of the first conductive layer 21, thereby avoiding coupling or a short circuit between the second conductive layer 22 and another surrounding structure. The remaining conductive material layer 210 after the etching may be defined as the first conductive layer 21.

In some implementations of the present invention, etching may be performed through dry etching. The etching gas may be carbon tetrafluoride or another gas that can remove the conductive material layer 210 without damaging another structure.

In step 240 (S240), Form the second conductive layer 22 on a surface of the first conductive layer 21.

A second conductive layer 22 may be formed on a surface of the first conductive layer 21 by using a process such as physical vapor deposition, chemical vapor deposition, atomic layer deposition, vacuum evaporation, or magnetron sputtering. The second conductive layer 22 may cover a surface of the first conductive layer 21 disposed in the array region 101. An orthographic projection of the second conductive layer 22 on the substrate 1 does not overlap the peripheral region 102, and the orthographic projection of the second conductive layer 22 on the substrate 1 may overlap the array region 101.

In some example implementations of the present invention, referring to FIG. 2 and FIG. 3, a thickness of the second conductive layer 22 may be equal to a height difference between the first conductive layer 21 at the array region 101 and the first conductive layer 21 at the peripheral region 102, that is, a surface of the second conductive layer 22 may be flush with a surface of the first conductive layer 21 of the peripheral region 102, and the second conductive layer 22 covers only the surface of the first conductive layer 21 in the array region 101. In such case, compared with a conventional technology (in which the second conductive layer 22 covers the entire surface of the first conductive layer 21), when the structure formed by the second conductive layer 22 and the first conductive layer 21 occupies a same space, a volume ratio of the first conductive layer 21 to the second conductive layer 22 in the word line structure 2 in some implementations of the present invention is higher than that of the conventional technology. Because a material of the first conductive layer 21 is a metal material, a proportion of a metal material in the word line structure 2 can be increased, thereby reducing the resistance of the word line structure 2.

In some example implementations of the present invention, the forming the second conductive layer 22 on a surface of the first conductive layer (that is, step S240) may include steps S310 and S320.

In step 310 (S310), a semiconductor material layer 310 is formed on a surface of a structure jointly formed by the word line structure 2 and the substrate 1.

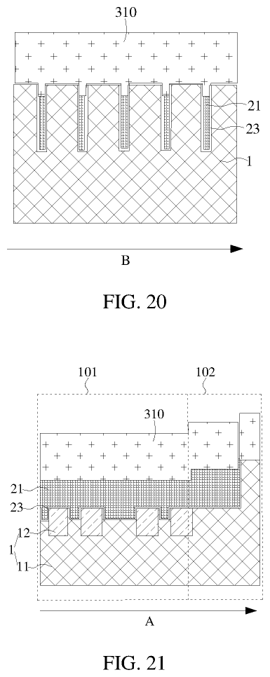

Referring to FIG. 20 and FIG. 21, the semiconductor material layer 310 may be formed on the surface of the structure jointly formed by the word line structure 2 and the substrate 1 by using a process such as physical vapor deposition, chemical vapor deposition, atomic layer deposition, vacuum evaporation, or magnetron sputtering. A thickness of the semiconductor material layer 310 may be greater than a height difference between a surface of the word line structure 2 disposed in the array region 101 and the surface of the substrate 1, that is, the semiconductor material layer 310 may fill each of the word line trenches 201 and may cover an entire surface of the substrate 1.

In step 320 (S320), the semiconductor material layer 310 disposed outside the word line trenches 201 is removed, and a part of the semiconductor material layer 310 is further removed until a surface of the semiconductor material layer 310 disposed in the array region 101 is flush with a surface of the first conductive layer 21 at the peripheral region 102.

Referring to FIG. 2 and FIG. 3, the semiconductor material layer 310 may be etched until the semiconductor material layer 310 disposed on the surface of the peripheral region 102 is completely removed. In addition, in the etching process, a surface of the semiconductor material layer 310 disposed in the array region 101 may be flush with a surface of the first conductive layer 21 at the peripheral region 102. The remaining semiconductor material layer 310 after the etching may be defined as the second conductive layer 22.

In some example implementations of the present invention, the method for forming a semiconductor structure may further include step 130 (S130)

In S130, an insulating layer 5 is formed on a top of the word line structure 2. The orthographic projection of the insulating layer 5 on the substrate 1 covers an orthographic projection of each word line structure 2 on the substrate 1.

Referring to FIG. 9 and FIG. 10, the insulating layer 5 may be a film formed on a surface of the word line structure 2, or may be a coating formed on a surface of the word line structure 2. A form of the insulating layer 5 is not specifically limited herein. An orthographic projection of the insulating layer 5 on the substrate 1 may cover an orthographic projection of each word line structure 2 on the substrate 1. The insulating layer 5 may protect the word line structure 2 to avoid damage to the surface of the word line structure 2. In addition, the word line structure 2 may be isolated from another structure by using the insulating layer 5 to avoid coupling or a short circuit between the word line structure 2 and another structure, thereby increasing a product yield.

In some implementations of the present invention, the insulating layer 5 may cover both the surface of the second conductive layer 22 and the surface of the first conductive layer 21 disposed on the surface of the peripheral region 102, that is, the insulating layer 5 may cover a surface of a structure that is jointly formed by the first conductive layer 21 and the second conductive layer 22. The insulating layer 5 may protect the first conductive layer 21 and the second conductive layer 22 to avoid damage to the surfaces of the first conductive layer 21 and the second conductive layer 22. In addition, the first conductive layer 21 and the second conductive layer 22 may be isolated from another structure by the insulating layer 5, to avoid coupling or a short circuit between another structure and each of the first conductive layer 21 and the second conductive layer 22, thereby increasing a product yield.

For example, a material of the insulating layer 5 may be silicon nitride or another insulating material. The insulating layer 5 may be formed, through chemical vapor deposition, physical vapor deposition, atomic layer deposition, thermal evaporation, vacuum evaporation, magnetron sputtering, or the like, on the surface of the structure jointly formed by the first conductive layer 21 and the second conductive layer 22. Certainly, the insulating layer 5 may alternatively be formed in another method. A method for forming the insulating layer 5 is not specifically limited herein.

In some example implementations of the present invention, the method for forming a semiconductor structure may further include step 140 (S140).

In S140, a word line contact plug 6 is formed in the peripheral region 102. A bottom surface of the word line contact plug 6 is connected to the first conductive layer 21.

Referring to FIG. 11 and FIG. 12, the word line contact plug 6 may be formed in the peripheral region 102, that is, an orthographic projection of the second conductive layer 22 on the substrate 1 does not overlap an orthographic projection of the word line contact plug 6 on the substrate 1. In addition, the second conductive layer 22 may be spaced apart from the word line contact plug 6. For example, there may be a first distance between one end of the second conductive layer 22 close to the peripheral region 102 and the word line contact plug 6. The first distance may be less than a length of the first conductive layer 21 in the peripheral region 102 in the first direction A, thereby to isolate the word line contact plug 6 from the second conductive layer 22, and avoiding damage to the second conductive layer 22 caused by formation of the word line contact plug 6.

Referring to FIG. 12, a bottom surface of the word line contact plug 6 may be directly connected to the surface of the first conductive layer 21 disposed in the peripheral region 102, so that the word line structure 2 is electrically led out by using the word line contact plug 6, and further, a data signal in the word line structure 2 may be led out by using the word line contact plug 6.

In some implementations of the present invention, one end of the word line contact plug 6 is connected to the word line structure 2, and the other end of the word line contact plug 6 may be connected, by using a peripheral contact plug 7, to a word line driver, a sense amplifier, a row decoder, a column decoder, and/or a controlling circuitry having a special function. The controlling circuitry can control the word line structure 2 and the bit line structure through current transfer by using the word line contact plug 6, thereby implementing write and read functions of the transistors and capacitors.

In some implementations of the present invention, referring to FIG. 12, the word line contact plug 6 may penetrate the insulating layer 5 in a normal direction of the substrate 1, that is, the word line contact plug 6 may be embedded into the insulating layer 5, and the insulating layer 5 may protect the word line contact plug 6. In such a process, coupling or a short circuit between the word line contact plug 6 and another surrounding structure may be avoided, thereby further increasing a product yield.

In some implementations of the present invention, a word line contact plug 6 is formed in the peripheral region 102, where a bottom surface of the word line contact plug 6 is connected to the first conductive layer 21 (that is, step S140), which may include steps S1401 and S1402.

In step 1401 (S1401), a first contact hole 601 that penetrates the insulating layer 5 is formed. The first contact hole 601 exposes the word line structure 2.

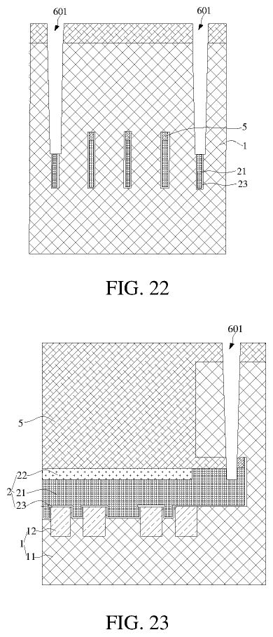

Referring to FIG. 22 and FIG. 23, a first contact hole 601 may be formed in the peripheral region 102 by using an etching process, and the first contact hole 601 may expose a word line structure 2. In some embodiments, the first contact hole 601 may alternatively be formed in another method. A method for forming the first contact hole 601 is not specifically limited herein.

It should be noted that, because the first contact hole 601 is formed in the peripheral region 102, and a surface of the word line structure 2 disposed in the peripheral region 102 is not covered by the second conductive layer 22, in a process of etching to form the first contact hole 601, the first contact hole 601 does not need to penetrate the second conductive layer 22, and therefore, no etching solution or etching gas with a relatively high etching rate is required to etch the second conductive layer 22, thereby avoiding damage to the substrate 1 and the array region 101 in a process of forming the first contact hole 601. As such, defects generated in the substrate 1 are reduced, and a product yield is improved. In addition, in the above-mentioned process, because no second conductive layer 22 is disposed on the peripheral region 102, in a process of forming the first contact hole 601, there is no need to etch the second conductive layer 22, thereby reducing the layers to be etched, simplifying the manufacturing process (that is, reducing a process of etching the second conductive layer 22), and reducing manufacturing costs. In addition, because the height of the first conductive layer 21 is increased, the depth for etching the via hole (first contact hole 601) is reduced, and processing difficulty may be reduced.

The first contact hole 601 may be a circular hole, an elliptical hole, a rectangular hole, or a hole-like structure of another shape. A shape of the first contact hole 601 is not specifically limited herein, provided that a word line structure 2 can be exposed. There may be a plurality of first contact holes 601. For example, a quantity of first contact holes 601 may be equal to a quantity of word line structures 2, and the first contact holes 601 may expose the word line structures 2 in a one-to-one correspondence.

In step 1402 (S1402), the first contact hole 601 is filled with a metal conductive material to form the word line contact plug 6.

Each first contact hole 601 may be filled with a metal conductive material to form a word line contact plug 6 in each first contact hole 601. For example, each first contact hole 601 may be filled with the first conductive material by using a process such as electroplating, vacuum evaporation, magnetron sputtering, chemical vapor deposition, physical vapor deposition, atomic layer deposition, or thermal evaporation to form the word line contact plug 6.

In some implementations of the present invention, the metal conductive material may be titanium nitride or tungsten, or certainly may be another material with relatively strong conductive performance, which is not listed one by one herein.

In some example implementations of the present invention, the method for forming a semiconductor structure may further include:

In step 150 (S150), a peripheral contact plug 7 is formed in the peripheral region 102. The peripheral contact plug 7 is electrically connected to the word line contact plug 6. In the normal direction of the substrate 1, a top surface of the peripheral contact plug 7 has a same height as a top surface of the word line contact plug 6.

Referring to FIG. 13, the peripheral contact plug 7 may be disposed in the peripheral region 102, and one end of the peripheral contact plug 7 may be connected to source/drain 110 of a transistor in the peripheral region 102. In the normal direction of the substrate 1, the peripheral contact plug 7 may penetrate the insulating layer 5, and may be spaced from the word line contact plug 6. A height of a top surface of the peripheral contact plug 7 may be the same as a height of a top surface of the word line contact plug 6.

In some implementations of the present invention, the peripheral contact plug 7 may be electrically connected to the word line contact plug 6 by using a connection wire disposed on the surface of the insulating layer 5, so that the peripheral circuit can control components in the array region 101.

In some implementations of the present invention, a peripheral contact plug 7 is formed in the peripheral region 102, where the peripheral contact plug 7 is electrically connected to the word line contact plug 6, and in the normal direction of the substrate 1, a top surface of the peripheral contact plug 7 has a same height as a top surface of the word line contact plug 6 (that is, step S150), which may include steps S1501 and S1502.

In step 1501 (S1501), a second contact hole 701 that penetrates the insulating layer 5 is formed. The second contact hole 701 exposes source/drain 110 of a transistor of the peripheral region 102.

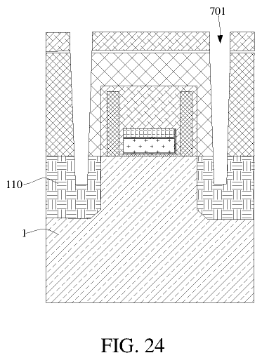

As shown in FIG. 24, the insulating layer 5 disposed in the peripheral region 102 may be etched by using an etching process to form a second contact hole 701 in the peripheral region 102. The second contact hole 701 may expose a source drain 110 of the transistor in the peripheral region 102. Certainly, the second contact hole 701 may alternatively be formed in another method. A method for forming the second contact hole 701 is not specifically limited herein.

The second contact hole 701 may be a circular hole, an elliptical hole, a rectangular hole, or a hole-like structure of another shape. A shape of the second contact hole 701 is not specifically limited herein, provided that the source drain 110 of the transistor in the peripheral region 102 can be exposed. There may be a plurality of second contact holes 701. For example, a quantity of second contact holes 701 may be equal to a quantity of transistors in the peripheral region 102, and the second contact holes 701 may expose the source drains 110 of the transistors in the peripheral region 102 in a one-to-one correspondence.

In step 1502 (S1502), the second contact hole 701 is filled with a second conductive material to form the peripheral contact plug 7.

Each second contact hole 701 may be filled with a second conductive material to form a peripheral contact plug 7 in each second contact hole 701. For example, each second contact hole 701 may be filled with the second conductive material by using a process such as electroplating, vacuum evaporation, magnetron sputtering, chemical vapor deposition, physical vapor deposition, atomic layer deposition, or thermal evaporation to form the peripheral contact plug 7.

In some implementations of the present invention, the second conductive material and the first conductive material may be the same or different, which is not specifically limited herein. For example, the second conductive material may be titanium nitride or tungsten, or certainly may be another material with relatively strong conductive performance, which is not listed one by one herein.

It should be noted that, although the steps of the method for forming a semiconductor structure in the present invention are described in the accompanying drawings in a particular sequence, it does not require or imply that these steps necessarily be performed in that particular sequence, or that all steps shown necessarily be performed to achieve a desired result. Additionally or alternatively, some steps may be omitted, a plurality of steps may be combined into one step for execution, and/or a step may be broken down into a plurality of steps for execution, or the like.

Some embodiments of the present invention further provide a memory. The memory may include the semiconductor structure in any one of the above-mentioned embodiments. Specific details, forming processes, and beneficial effects of the semiconductor structure are already described in detail in the corresponding semiconductor structure and the corresponding method for forming a semiconductor structure. Details are not described herein again.

For example, the memory may be a dynamic random access memory (DRAM), a static random access memory (SRAM), or the like. Certainly, the memory may alternatively be another storage apparatus, which is not listed one by one herein.

After considering the specification and practicing the invention disclosed herein, a person skilled in the art easily figures out other implementation solutions of the present invention. This application is intended to cover any variations, functions, or adaptive changes of the present invention. These variations, functions, or adaptive changes comply with general principles of the present invention, and include common knowledge or a commonly used technical means in the technical field that is not disclosed in the present invention. This specification and some embodiments are merely considered as examples, and the actual scope and the spirit of the present invention are pointed out by the appended claims.

What is claimed is:

1. A semiconductor structure, comprising:
a substrate, comprising an array region and a peripheral region; and
a word line structure, comprising a first conductive layer disposed on the substrate, wherein the first conductive layer penetrates the array region and extends to the peripheral region in a first direction; in a normal direction of the substrate, a height of the first conductive layer on a surface of the peripheral region is higher than a height of the first conductive layer on a surface of the array region.

2. The semiconductor structure according to claim 1, wherein the semiconductor structure further comprises:
a word line contact plug, disposed in the peripheral region, wherein a bottom surface of the word line contact plug is connected to the first conductive layer.

3. The semiconductor structure according to claim 2, wherein the word line structure further comprises:
a second conductive layer, wherein the second conductive layer is disposed on the first conductive layer, and an orthographic projection of the second conductive layer on the substrate does not overlap an orthographic projection of the word line contact plug on the substrate.

4. The semiconductor structure according to claim 3, wherein one end of the second conductive layer close to the peripheral region and the word line contact plug are separated by a first distance, and the first distance is less than a length of the first conductive layer in the peripheral region in the first direction.

5. The semiconductor structure according to claim 3, wherein a surface of the first conductive layer in the peripheral region is flush with a surface of the second conductive layer.

6. The semiconductor structure according to claim 3, wherein a material of the first conductive layer is a metal material, and a material of the second conductive layer is a semiconductor material.

7. The semiconductor structure according to claim 3, wherein the semiconductor structure further comprises:
a peripheral contact plug, disposed in the peripheral region and electrically connected to the word line contact plug, wherein in the normal direction of the substrate, a top surface of the peripheral contact plug has a same height as a top surface of the word line contact plug.

8. The semiconductor structure according to claim 3, wherein the word line structure further comprises a gate dielectric layer, and the gate dielectric layer at least conformally covers sidewall surfaces of the first conductive layer and the second conductive layer.

9. A method for forming a semiconductor structure, comprising:
providing a substrate, wherein the substrate comprises an array region and a peripheral region; and
forming a plurality of word line structures in the substrate, wherein the word line structure comprises a first conductive layer disposed on the substrate, and the first conductive layer penetrates the array region and extends to the peripheral region in a first direction; in a normal direction of the substrate, a height of the first conductive layer on a surface of the peripheral region is higher than a height of the first conductive layer on a surface of the array region.

10. The method according to claim 9, further comprising:
forming a word line contact plug in the peripheral region, wherein a bottom surface of the word line contact plug is connected to the first conductive layer.

11. The method according to claim 10, further comprising:
forming a second conductive layer on the first conductive layer, wherein an orthographic projection of the second conductive layer on the substrate does not overlap an orthographic projection of the word line contact plug on the substrate.

12. The method according to claim 11, wherein one end of the second conductive layer close to the peripheral region and the word line contact plug are separated by a first distance, and the first distance is less than a length of the first conductive layer in the peripheral region in the first direction.

13. The method according to claim 11, wherein a surface of the first conductive layer in the peripheral region is flush with a surface of the second conductive layer.

14. The method according to claim 11, wherein a material of the first conductive layer is a metal material, and a material of the second conductive layer is a semiconductor material.

15. The method according to claim 11, further comprising:
forming a peripheral contact plug in the peripheral region, wherein the peripheral contact plug is electrically connected to the word line contact plug, and in the normal direction of the substrate, a top surface of the peripheral contact plug has a same height as a top surface of the word line contact plug.

16. The method according to claim 11, wherein the word line structure further comprises a gate dielectric layer, and the gate dielectric layer at least conformally covers sidewall surfaces of the first conductive layer and the second conductive layer.

17. The method according to claim 16, wherein the forming a plurality of word line structures in the substrate comprises:
forming a plurality of word line trenches in the substrate, wherein the word line trenches penetrate the array region and the peripheral region;
conformally forming, in each of the word line trenches, a gate dielectric layer attached to a sidewall of the word line trench;
forming the first conductive layer in each of the word line trenches having the gate dielectric layer; and
forming the second conductive layer on a surface of the first conductive layer.

18. The method according to claim 17, wherein the forming the first conductive layer in each of the word line trenches having the gate dielectric layer comprises:
forming a conductive material layer on a surface of the substrate, wherein the conductive material layer fills the word line trench having the gate dielectric layer;
forming a second photoresist layer on a surface of the conductive material layer, wherein an orthographic projection of the second photoresist layer on the substrate coincides the peripheral region;
etching the conductive material layer partially disposed in the array region with the second photoresist layer served as a mask, until a surface of the conductive material layer in the array region is flush with the surface of the substrate;
removing the second photoresist layer; and
etching a remaining conductive material layer until a surface of the conductive material layer disposed in the peripheral region is lower than a surface of the substrate and higher than the surface of the conductive material layer disposed in the array region.

19. The method according to claim 17, wherein the forming the second conductive layer on a surface of the first conductive layer comprises:
forming a semiconductor material layer on a surface of a structure that is jointly formed by the gate dielectric layer, the first conductive layer, and the substrate; and
removing the semiconductor material layer disposed outside the word line trenches, and continuing to remove a part of the semiconductor material layer until a surface of the semiconductor material layer disposed in the array region is flush with a surface of the first conductive layer disposed in the peripheral region.

20. A memory, comprising a semiconductor structure, wherein the semiconductor structure comprises:
a substrate, comprising an array region and a peripheral region; and
a word line structure, comprising a first conductive layer disposed on the substrate, wherein the first conductive layer penetrates the array region and extends to the peripheral region in a first direction; in a normal direction of the substrate, a height of the first conductive layer on a surface of the peripheral region is higher than a height of the first conductive layer on a surface of the array region.
